(19) United States
(12) Patent Application Publication
(10) Pub. No.: US 2006/0118407 A1
(43) Pub. Date: Jun. 8, 2006

(54) Methods for making low silicon content ni-si sputtering targets and targets made thereby

(75) Inventor: Eugene Y. Ivanov, Grove City, OH (US)

Correspondence Address: WEGMAN, HESSLER & VANDERBURG, 6055 ROCKSIDE WOODS BOULEVARD, SUITE 200, CLEVELAND, OH, 44131, US

(73) Assignee: Tosoh SMD, Inc., Grove City, OH (US)

(21) Appl. No.: 10/554,810

(22) PCT Filed: Apr. 29, 2004
(86) PCT No.: PCT/US04/13168

§ 371 Date: Jan. 13, 2006

Related U.S. Application Data
(60) Provisional application No. 60/467,354, filed on May 2, 2003.

(51) Int. Cl. C22C 19/03; C23C 14/14

(52) U.S. Cl. 204/192.25; 420/441

(57) ABSTRACT

A method for making nickel/silicon sputter targets, targets made thereby and sputtering processes using such targets. Molten nickel is blended with sufficient molten silicon and cast to form an alloy containing trace amounts, up to less than 4.39 wt % silicon, and preferably 2.0 wt % silicon. Preferably, the cast ingot is then shaped by rolling it to form a plate having a desired thickness. Sputter targets so formed are capable of use in conventional magnetron sputter processes, such that a target can be positioned near a cathode in the presence of an electric potential difference and a magnetic field in order to induce sputtering of nickel ions from the sputter target onto the substrate.

### CROSS REFERENCE TO RELATED APPLICATION

This application claims the benefit of U.S. Provisional Patent Application Ser. No. 60/467,354 filed May 2, 2003.

### BACKGROUND OF THE INVENTION

1. Field of Invention

The present invention relates to methods for making sputter targets, sputter targets made thereby, and methods of sputtering using such targets. More particularly, the invention relates to the manufacture of sputter targets using nickel-silicon alloys and to targets manufactured thereby.

2. Description of Related Art

Cathodic sputtering is widely used for depositing thin layers or films of materials from sputter targets onto desired substrates such as semiconductor wafers. Basically, a cathode assembly including a sputter target is placed together with an anode in a chamber filled with an inert gas, preferably argon. The desired substrate is positioned in the chamber near the anode with a receiving surface oriented normally to a path between the cathode assembly and the anode. A high voltage electric field is applied across the cathode assembly and the anode.

Electrons ejected from the cathode assembly ionize the inert gas. The electrical field then propels positively charged ions of the inert gas against a sputtering surface of the sputter target. Material dislodged from the sputter target by the ion bombardment traverses the chamber and deposits on the receiving surface of the substrate to form the thin layer or film.

In so-called magnetron sputtering, one or more magnets are positioned behind the cathode assembly to generate a magnetic field. Magnetic fields generally can be represented as a series of flux lines, with the density of such flux lines passing through a given area, referred to as the “magnetic flux density,” corresponding to the strength of the field. In a magnetron sputtering apparatus, the magnets form arch-shaped flux lines which penetrate the target and serve to trap electrons in annular regions adjacent the sputtering surface. The increased concentrations of electrons in the annular regions adjacent the sputtering surface promote the ionization of the inert gas in those regions and increase the frequency with which the gas ions strike the sputtering surface beneath those regions.

Nickel is commonly used in physical vapor deposition (“PVD”) processes for forming nickel silicide films by means of the reaction of deposited nickel with a silicon substrate. Yet, while magnetron sputtering methods have improved the efficiency of sputtering many target materials, such methods are less effective in sputtering “ferromagnetic” metals such as nickel. It has proven difficult to generate a sufficiently strong magnetic field to penetrate a nickel sputter target to efficiently trap electrons in the annular regions adjacent the sputtering surface of the target.

As background to the magnetic behavior of metals, the magnetic flux density vector within a metal body generally differs from the magnetic flux density external to the body. Typically, the component “B” of the magnetic flux density along a given direction in space within a metal body may be expressed in accordance with the relationship B=μ (H+M), where “μ” is a constant referred to as the magnetic permeability of empty space; “H” is the corresponding component of the so-called “magnetic field intensity” vector; and “M” is the corresponding component of the so-called “magnetization” vector. (Note that positive and negative values of the components of the magnetic flux density, the magnetic field intensity and the magnetization represent opposite directions in space, respectively.)

The magnetic field intensity may be thought of as the contribution to the internal magnetic flux density due to the penetration of the external magnetic field into the metallic body. The magnetization may be thought of as the contribution to the internal magnetic flux density due to the alignment of magnetic fields generated primarily by the electrons within the metal.

In “paramagnetic” materials, the magnetic fields generated within the metal tend to align so as to increase the magnetic flux density within the metal. Furthermore, the magnetic fields generated within a paramagnetic metal do not strongly interact and cannot stabilize the alignment of the magnetic fields generated within the metal, so that the paramagnetic metal is incapable of sustaining any residual magnetic field once the external magnetic field is removed. Thus, for many paramagnetic metals and at a constant temperature, the “magnetization curve,” which relates the magnetic flux density to the magnetic field strength within the metal, is linear and independent of the manner in which the external magnetic field is applied.

In a “ferromagnetic” metal such as nickel, the magnetic fields generated within the metal do interact sufficiently for the metal to retain a residual magnetic field when the external field is removed. Below a “Curie temperature” characteristic of a ferromagnetic metal, the metal must be placed in an external magnetic field directed oppositely to the residual field in the metal in order to dissipate the residual field.

At any constant temperature below the Curie temperature, the relationship between the magnetic flux density and the magnetic field intensity in the metal differs depending on how the external magnetic field has varied over time. For example, if a ferromagnetic metal is magnetized to its maximum, or “saturation,” flux density in one direction in space and then the external magnetic field is slowly reversed to the opposite direction, the magnetic flux density within the metal will decrease as a function of the magnetic field intensity along a first path until the magnetic flux within the metal reaches the negative of the saturation value. If the external field is again reversed so as to re-magnetize the metal in the original direction, the magnetic flux density within the metal will increase as a function of the magnetic field intensity along a second path which differs from the first path in relation to the reversal of the residual magnetic field. The shape of the resulting dual-path magnetization curve, which is referred to as a “hysteresis loop,” is characteristic of ferromagnetic behavior.

When a ferromagnetic metal is surrounded by a gas in the presence of a magnetic field, the ferromagnetic metal tends to “attract” the flux lines of the magnetic field away from the surrounding gas into itself. This prevents the flux lines from penetrating the ferromagnetic metal and extending through to the surrounding gas. While paramagnetic metals may “attract” some flux lines of an external magnetic field, they do so to a far lesser degree than do ferromagnetic materials.

Above their Curie temperatures, nominally ferromagnetic metals behave in a manner similar to paramagnetic materials. In particular, nominally ferromagnetic metals tend to “attract” far less of the flux of an external magnetic field into themselves above their Curie temperatures than below.

Thus, without wishing to be bound by any theory of operation, it is believed that a nickel sputter target placed in the magnetic field of a magnetron sputtering device tends to “attract” the flux of the magnetic field into itself. This prevents the magnetic flux from penetrating through the target, thereby reducing the efficiency of the magnetron sputtering process.

Typically, only thin nickel targets of about 0.12 inch (3 mm) or less could be used in magnetron sputtering processes due to the ferromagnetic character of nickel. This increases the difficulty and cost of sputtering nickel, since it is necessary to replace the sputter targets at frequent intervals.

Meckel U.S. Pat. No. 4,229,678 sought to overcome this problem by heating the target material to its Curie temperature and magnetron sputtering the material while in such a state of reduced magnetization. Meckel further proposed a magnetic target plate structured to facilitate heating of the plate to its Curie temperature by the thermal energy inherent in the sputtering process. One drawback to this proposed method was the increased cost inherent in providing for the heating of the target as well as providing for the stability of the cathode assembly at increased temperatures.

The problem of magnetron sputtering nickel has been addressed in the specialty media industry by alloying the nickel with another transition metal such as vanadium. At about 12 at. % vanadium, the alloy ceases to behave ferromagnetically. Alloys of nickel with other transition metals such as chromium, molybdenum and titanium have shown a loss of ferromagnetic behavior at compositions under 15 at. %. Adopting a similar approach, Wilson U.S. Pat. No. 4,094,761 proposed alloying nickel with copper, platinum or aluminum to produce an alloy having a Curie temperature below the sputtering temperature. Unfortunately, all of these methods share the drawback that the metals alloyed with the nickel constitute impurities when the sputter target is used in a nickel silicidation process.

Another approach that has been taken is illustrated in PCT Publication WO 99/25892 (of common assignment herewith), published May 27, 1999. As an alternative to the instant invention, NiSi targets are reported wherein the Si content is on the order of about 4.5 wt % and greater. These targets have acceptable PTF (pass through flux) characteristics. Although these targets represent a considerable advance in the art, it is still desirable to provide very low Si content Ni/Si targets that exhibit acceptable PTF characteristics while improving upon the uniformity of the thin films supported thereby.

### SUMMARY OF THE INVENTION

These and other objects of the invention are met by a method for making a nickel/silicon sputter target including the step of blending molten nickel with sufficient molten silicon so that the blend may be cast to form an alloy containing trace amounts (i.e., 0.001 wt %) up to less than about 4.39 wt % silicon, preferably about 2.0 wt % Si. The cast ingot is then shaped by rolling it to form a plate having a desired thickness and then the rolled plate is machined to form the desired target shape. The sputter target so formed is capable of use in a conventional magnetron sputter process; that is, it can be positioned near a cathode in cathodic sputtering operations, in the presence of an electric potential difference and a magnetic field so as to induce sputtering of nickel ion from the sputter target onto the substrate. However, these targets can be made thicker than conventional Ni targets so that they may be used for longer sputtering times without replacement.

In addition, it has been found that rolling the ingot formed from casting the nickel-silicon alloy before machining the target promotes the deposition of a uniform layer of nickel silicide during the sputtering process.

### DETAILED DESCRIPTION OF EXEMPLARY EMBODIMENTS

In accordance with an especially preferred method for making a sputter target, nickel and silicon are blended as powders or small blocks in a crucible and melted in an induction or resistance furnace. Preferably, the blend is then cast to form an ingot containing at least trace amounts, up to about 4.5 wt % silicon. The ingot is rolled to form a plate having a desired thickness (i.e., greater than 0.12 inch (3 mm)). Finally, the plate is machined to form the target. Targets in accordance with the invention accordingly include from about 0.001 wt % silicon to less than about 4.39 wt % silicon. More preferably, the targets comprise NiSi 0.1 wt %-3.00 wt %, more preferably NiSi 0.5-2.5 wt %. At present, preferred targets are NiSi 2.0 wt %

The nickel and silicon may be blended either in the form of powders or of small blocks. Preferably, the blending occurs in a crucible, which may be inserted into an induction or resistance furnace to melt the nickel and silicon. For example, the nickel may be introduced in the form of 1 cubic inch blocks which are melted in a crucible before blending with the silicon.

The casting, rolling and machining of the metal may be carried out by conventional means well known to those of ordinary skill in the art.

The inclusion of trace amounts, up to less than about 4.39 wt %. silicon, and preferably 2.0 wt % silicon, has been found to render better sputtering uniformity. Further, sputter targets comprised of the trace amounts, up to less than about 4.39 wt % silicon, and preferably 2.0 wt % silicon, tend to have better magnetic pass through flux than occurs in targets comprised totally of nickel.

The invention will be further described by means of the following examples, which are illustrative only and not limitative of the invention as claimed.

### EXAMPLE 1

Three 10 g blends of nickel and silicon powders are prepared, melted in crucibles, and cast to form silicon alloy ingots having the following content.

| | |
|---|---|
| NiSi | 0.10 wt % |
| NiSi | 1.00 wt % |
| NiSi | 1.50 wt % |
| NiSi | 2.00 wt % |
| NiSi | 2.50 wt % |
| NiSi | 3.00 wt % |
| NiSi | 3.50 wt % |
| NiSi | 4.00 wt % |
| NiSi | 4.38 wt % |

### EXAMPLE 2

Nickel-silicon alloy targets are formed from the ingots detailed in Example 1. The 2.0 wt % Si target especially will result in improved sputtering uniformity.

In addition, it has been found that rolling the ingots formed from casting the nickel-silicon alloys before machining the target promotes the formation of uniform grain sizes in the alloys, which, in turn, promotes the deposition of uniform layers of nickel silicide during the sputtering processes. Since no transition metals are alloyed with the nickel to lower its Curie temperature, no impurities are introduced when such targets are used in nickel silicidation processes.

While the method described herein and the sputter targets produced in accordance with the method constitute preferred embodiments of the invention, it is to be understood that the invention is not limited to these precise methods and sputter targets, and that changes may be made in either without departing from the scope of the invention, which is defined in the appended claims.

1. A sputter target comprising a nickel/silicon alloy, said silicon being present in an amount from about 0.001—to less than about 4.39 wt %.

2. The sputter target as recited in claim 1 wherein the silicon is present in an amount of about 0.1-3.00 wt %.

3. The sputter target as recited in claim 2, wherein said Si is present in an amount of about 0.5-2.5 wt %.

4. The sputter target as recited in claim 3, wherein the silicon is present in an amount of about 2.0 wt %.

5. Sputter target as recited in claim 1 wherein Si is present in an amount of about 4.0 wt %.

6. Sputter target as recited in claim 1 wherein Si is present in an amount of about 4.38 wt %.

7. Sputter target as recited in claim 1 wherein said Si is present in an amount of about 3.5 wt %.

8. Sputter target as recited in claim 1 wherein said Si is present in an amount of about 3.0 wt %.

9. Sputter target as recited in claim 1 wherein said Si is present in an amount of about 2.5 wt %.

10. Sputter target as recited in claim 1 wherein said Si is present in an amount of 2.0 wt %.

11. Sputter target as recited in claim 1 wherein said Si is present in an amount of about 1.5 wt %.

12. Sputter target as recited in claim 1 wherein said Si is present in an amount of about 1.0 wt %.

13. Sputter target as recited in claim 1 wherein said Si is present in an amount of about 0.10 wt %.

14. A method of sputter coating a nickel/silicon material onto a wafer comprising:
providing a magnetron sputtering system;
providing a nickel/silicon sputter target, the silicon being present in an amount of between trace amounts up to less than about 4.39 wt %;
providing a magnetic field through said target; and
sputtering said nickel/silicon material from said target onto said wafer, wherein the wafer is a silicon wafer.

15. The method of claim 14 wherein the silicon is present in an amount of about 2.0 wt %.

16. A method for preparing a sputter target comprising:
providing a mix of nickel and silicon, wherein the silicon is present in an amount of between a trace amount and up to less than about 4.39 wt %;
consolidating the mix into a blend of the nickel and the silicon; and
forming the consolidated blend into a shape desired for the sputter target.
